(19) United States
(12) Patent Application Publication
(10) Pub. No.: US 2024/0201264 A1
(43) Pub. Date: Jun. 20, 2024

(54) UNIFIED BATTERY-STATUS OBSERVABILITY

(71) Applicant: International Business Machines Corporation, Armonk, NY (US)

(72) Inventors: Robert Filepp, Westport, CT (US); Abdulhamid Adebowale Adebayo, White Plains, NY (US); William Anderson, Raleigh, NC (US); Neil Delima, Scarborough (CA)

(73) Assignee: International Business Machines Corporation, Armonk, NY (US)

(21) Appl. No.: 18/081,682

(22) Filed: Dec. 14, 2022

(51) Int. Cl. G01R 31/367; G01R 31/382; H01M 10/42

(52) U.S. Cl. CPC G01R 31/367; G01R 31/382; H01M 10/4207; H01M 10/4285

(57) ABSTRACT

A method for unifying battery-status observability across a plurality of heterogeneous devices includes identifying a plurality of heterogeneous devices where each device includes a battery to power the device. The method monitors battery status of each device of the heterogeneous devices. The method may also access crowdsourced data to determine battery life associated with at least one device of the heterogeneous devices. Using the battery status and potentially the crowdsourced data, the method predicts the remaining battery life for each device of the heterogeneous devices. The method presents the remaining battery life of each of the heterogeneous devices on a unified dashboard. In certain embodiments, a user may be alerted in the event the remaining battery life of a device of the heterogeneous devices falls below a selected threshold. A corresponding system and computer program product are also disclosed.

### BACKGROUND

### Field of the Invention

This invention relates to systems and methods for unifying battery-status observability across a plurality of heterogeneous devices.

### Background of the Invention

People and companies typically have a wide variety of devices (e.g., security cameras, mobile phones, computing devices, gaming devices, door bells, security alarms, lighting devices, etc.) to perform a wide variety of different functions. In many cases, these devices are battery powered to enable mobility of the devices and enable operation where wired power is not available or would unduly tether the device to an outlet or location. However, a loss of battery power may in many cases stop the function of a device. Thus, maintaining and monitoring the charge level and operation of a battery may be important to maintaining operation and functionality of the device.

In some cases and with some specific devices, an application, such as a mobile application, may be provided to enable a user to check the battery status, energy usage, or other characteristics of the device. However, because such applications are often device-specific, the user typically needs a wide variety of different applications to monitor all of his or her devices. This can be cumbersome and may, in certain cases, leave the user uninformed as to the battery status of his or her devices.

### SUMMARY

The invention has been developed in response to the present state of the art and, in particular, in response to the problems and needs in the art that have not yet been fully solved by currently available systems and methods. Accordingly, systems and methods have been developed to unify battery-status observability across a plurality of heterogeneous devices. The features and advantages of the invention will become more fully apparent from the following description and appended claims, or may be learned by practice of the invention as set forth hereinafter.

Consistent with the foregoing, a method for unifying battery-status observability across a plurality of heterogeneous devices is disclosed. In one embodiment, such a method identifies a plurality of heterogeneous devices where each device includes a battery to power the device. The method monitors battery status of each device of the heterogeneous devices. In certain embodiments, this may be performed with a monitoring agent that is installed on each device. The method may also access crowdsourced data to determine battery life associated with at least one device of the heterogeneous devices. Using the battery status and potentially the crowdsourced data, the method predicts the remaining battery life for each device of the heterogeneous devices. The method presents the remaining battery life of each of the heterogeneous devices on a unified dashboard. In certain embodiments, a user may be alerted in the event the remaining battery life of a device of the heterogeneous devices falls below a selected threshold.

A corresponding system and computer program product are also disclosed and claimed herein.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the embodiments of the invention will be described and explained with additional specificity and detail through use of the accompanying drawings, in which:

FIG. 1 is a high-level block diagram showing one example of a computing system for use in implementing embodiments of the invention;

FIG. 2 is a high-level block diagram showing one embodiment of a system for unifying battery-status observability across a plurality of heterogeneous devices;

FIG. 3 is a high-level block diagram showing a battery-status unification module and various sub-modules in accordance with the invention;

FIG. 4 is a high-level block diagram showing a monitoring agent and various internal sub-modules in accordance with the invention;

FIG. 5 shows one example of a standardized format that me used to represent battery status information for each heterogeneous device; and

FIG. 6 is a process flow diagram showing one embodiment of a method for unifying battery-status observability across a plurality of heterogeneous devices.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as code 150 (i.e., a “battery-status unification module 150”) for unifying battery-status observability across a plurality of heterogeneous devices. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

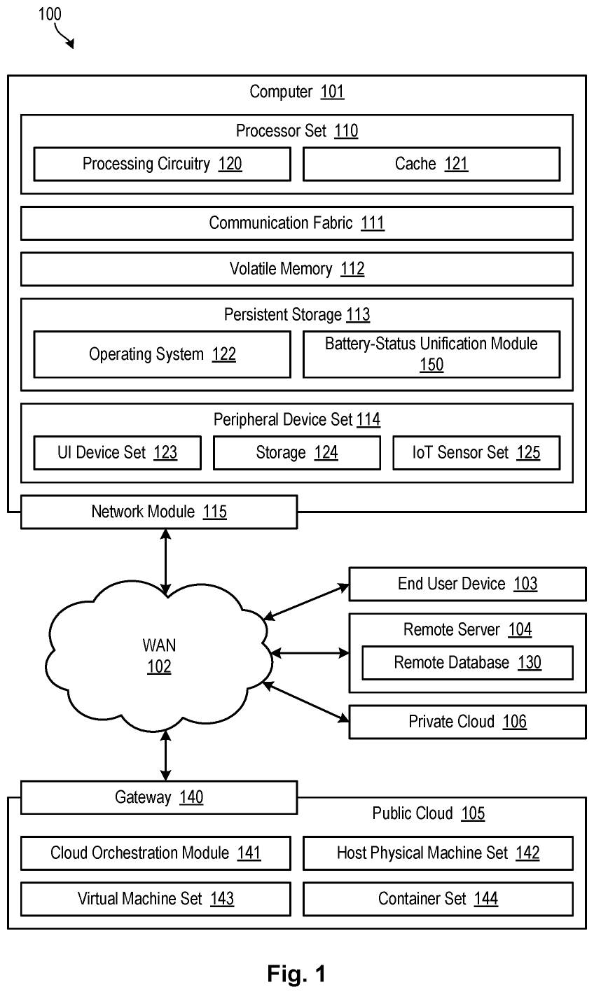

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

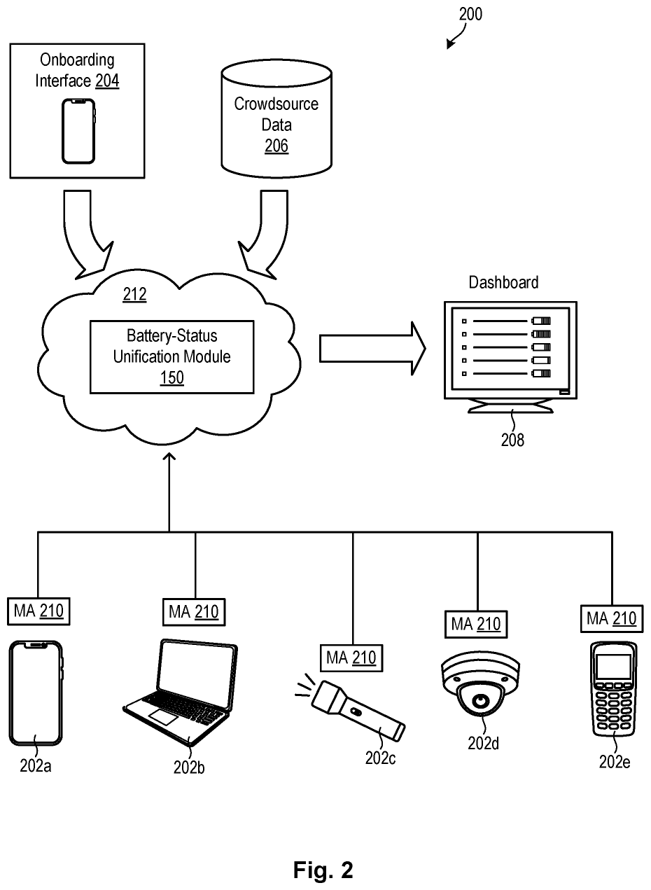

Referring to FIG. 2, as previously mentioned, people and entities such as companies may have a wide variety of devices 202 (e.g., mobile phones 202a, computing devices 202b, lighting devices 202c, security cameras 202d, door bells, computing devices, gaming devices, audio devices, etc.) to perform a wide variety of different functions. In many cases, these heterogeneous devices 202 are battery powered to allow the heterogeneous devices 202 to be mobile and to enable operation where wired power is not available or would unduly tether the device to an outlet or location. However, a loss of battery power may in many cases stop or hinder the function of a device 202. Thus, maintaining and monitoring the charge level and operation of a battery may be important to maintaining operation and functionality of the devices 202.

In some cases and with some specific heterogeneous devices 202, an application, such as a mobile application, may be provided to enable a user to check the battery status associated with a device 202. However, because such applications are often device-specific, the user may need a wide variety of different applications to monitor all of his or her heterogeneous devices 202. This can be cumbersome and may, in certain cases, leave the user uninformed as to the battery status of his or her heterogeneous devices 202.

FIG. 2 is a high-level block diagram showing one embodiment of a system 200 for unifying battery-status observability across a plurality of heterogeneous devices 202. For the purposes of this disclosure, heterogeneous devices 202 may include “smart devices” that have significant computing power and/or communication functionality, as well as “dumb devices” which may have little computing power and/or communication functionality. Each of these types of heterogeneous devices 202 may benefit from a battery-status unification module 150 in accordance with the invention.

In certain embodiments, where the heterogeneous devices 202 are somewhat “smart” with sufficient computing power, a monitoring agent 210 may be installed on the heterogeneous devices 202. The installation may be performed manually, or potentially remotely over a network connection after being granted permission by a device 202. These monitoring agents 210 may, in certain embodiments, be specifically tailored to device types, manufacturers, and/or operating systems. In certain embodiments, the monitoring agents 210 may leverage BIOS or operating-system-level libraries and/or utilities to collect battery status, energy usage, or other battery-related information.

In certain embodiments, the device 202 on which the monitoring agent 210 is installed should have either (1) two-way communications capability or (2) a timer and upstream communications capability. The monitoring agent 210 may then run either periodically when a timer is present, or on-demand or periodically when two-way communications capability is present. As will be explained in more detail hereafter, a monitoring agent 210 may collect battery status information from its respective device 202 and transmit this battery status information to a centralized hub 212. As shown, the centralized hub 212 may implement some or all of the functionality of the battery-status unification module 150 previously discussed. The centralized hub 212 may be located locally or remotely from the heterogeneous devices 202 and may communicate with the heterogeneous devices 202 over a network using a suitable wireless communication technology.

In certain embodiments, the monitoring agent 210 converts the battery status information to a standardized format prior to transmitting it to the centralized hub 212. Alternatively, the monitoring agent 210 may transmit the battery status information to the centralized hub 212 in a format that is native to the device 202 on which the monitoring agent 210 is installed. The centralized hub 212 may then convert the battery status information to the standardized format.

For devices that aren't smart enough to host a monitoring agent 210, an onboarding interface 204 may be provided. In certain embodiments, this onboarding interface 204 may take the form of a scanner or other data input mechanism (e.g., user interface, etc.) to receive information about the “dumb” devices so they can be identified and registered with the battery-status unification module 150. In certain embodiments, these “dumb” devices can be classified and assigned a uniform policy for each device class.

In some cases, “dumb” devices may be manually registered with the centralized hub 212 by way of the onboarding interface 204. For example, in one contemplated embodiment, the onboarding interface 204 may enable a user (or multiple users or a group administrator where the centralized hub 212 is being used to manage the heterogeneous devices 202 of an enterprise) to scan a product code or QR code of a device such as a flashlight to register the device with the centralized hub 212. The user may also potentially enter a policy into the centralized hub 212 that indicates that a notification should be sent when an expected battery life under a certain usage scenario reaches a selected threshold. As will be explained in more detail hereafter, the centralized hub 212 may, in certain embodiments, learn characteristics of the device (e.g., expected battery lifetime, etc.) from crowdsourced data 206 or other sources, and implement policies with respect to this crowdsourced data 206, such as sending a notification or issuing a recommendation to charge or replace the batteries when the expected battery life reaches a designated threshold.

As shown in FIG. 2, the centralized hub 212 and associated battery-status unification module 150 may, in certain embodiments, access crowdsourced data 206. This crowdsourced data 206 may, in certain embodiments, be compiled from a population of users of a particular device 202, whether it be a “dumb” device or a “smart” device. These users may provide, from their experience using the device 202, information regarding battery life, recharge times, battery replacement, etc. under different usage scenarios. The centralized hub 212 and battery-status unification module 150 may utilize this crowdsourced data 206 to make recommendations regarding a device 202, such as when to charge the battery, replace the battery, or the like. In other embodiments, if the battery-status unification module 150 is managing multiple of the same device 202, the battery-status unification module 150 may infer performance or characteristics of one device 202 based on experience with another of the same device 202.

The unified dashboard 208 may compile battery status information associated with the heterogeneous devices 202 for display on a single interface. Different types of information may be displayed for each of the heterogeneous devices 202. For example, one or more of a device identifier, device model, timestamp indicating the time that data was collected, battery energy level, battery energy capacity, energy usage rate, battery voltage and/or current, battery recharge time, remaining charge in a battery, percentage capacity remaining in a battery, charging state of a battery, or the like, may be displayed on the unified dashboard 208 for the heterogeneous devices 202. The unified dashboard 208 may provide a single location (as opposed to having to check a wide variety of applications) for displaying battery status information associated with heterogeneous devices 202 registered with the centralized hub 212. The unified dashboard 208 may be multi-modal in that it may be adapted for display on various types of devices, such as laptops, personal computers, smart phones, mobile devices, or the like.

In certain embodiments, the centralized hub 212 is configured to manage the battery-status observability of heterogeneous devices 202 for multiple enterprises. In such embodiments, each enterprise or user associated with the enterprise may have, through the centralized hub 212, battery-status observability of the heterogeneous devices 202 that are associated with that enterprise, while not having battery-status observability of the heterogeneous devices 202 of another enterprise with which they are not associated. Thus, the centralized hub 212 may, in certain embodiments, keep the heterogeneous devices 202 of one enterprise isolated from those of another enterprise while at the same time being able to manage the battery-status observability of heterogeneous devices 202 of multiple enterprises.

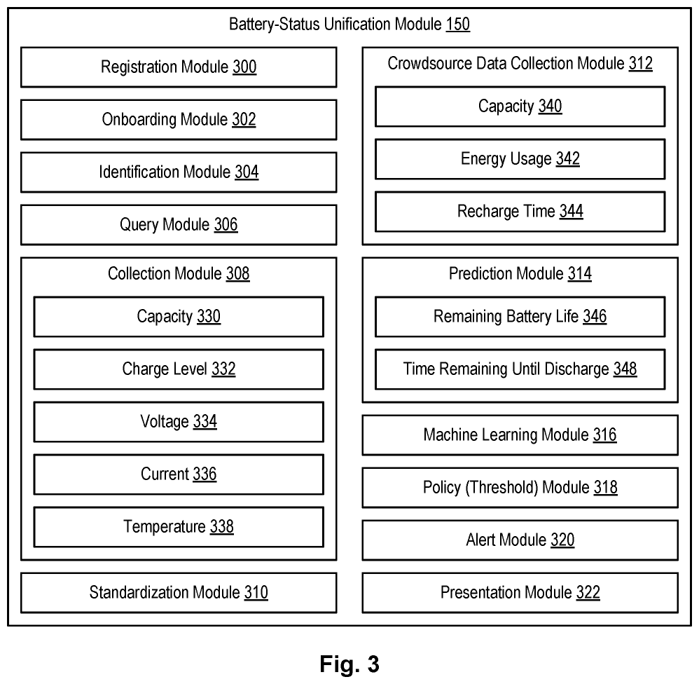

Referring to FIG. 3, a high-level block diagram showing a battery-status unification module 150 and associated sub-modules is illustrated. The battery-status unification module 150 and associated sub-modules may be implemented in hardware, software, firmware, or combinations thereof. The battery-status unification module 150 and associated sub-modules are presented by way of example and not limitation. More or fewer sub-modules may be provided in different embodiments. For example, the functionality of some sub-modules may be combined into a single or smaller number of sub-modules, or the functionality of a single sub-module may be distributed across several sub-modules.

As shown, the battery-status unification module 150 may include one or more of a registration module 300, onboarding module 302, identification module 304, query module 306, collection module 308, standardization module 310, crowdsourced data collection module 312, prediction module 314, machine learning module 316, policy module 318, alert module 320, and presentation module 322.

In order to unify battery-status observability across multiple heterogeneous devices 202, the registration module 300 may be used to initially register devices 202 with the battery-status unification module 150. Where the heterogeneous devices 202 are “smart” devices with two-way communication capability, this may include establishing a connection between the heterogeneous devices 202 and the battery-status unification module 150 using a suitable communication protocol (e.g., Bluetooth, Wifi, Zigbee, NFC, LoRA etc.). Where the heterogeneous devices 202 are “dumb” devices (e.g., with one-way or no communication capability), an onboarding module 302 may be used to register the devices 202 with the battery-status unification module 150. In certain embodiments, this may include scanning product information associated with the “dumb” device or manually entering the information through a user interface.

The identification module 304 may be used to identify the heterogeneous devices 202 that have been registered with the battery-status unification module 150. This may include identifying the heterogeneous devices 202 by one or more of a device identifier (e.g., name serial number, etc.) device type, model, manufacturer, battery type, current battery level, battery usage/consumption data, or the like. If a device 202 has more intelligent processing capability and network connectivity to the Internet or a private network, additional information may be captured such as the device's operating system, power source (AC, USB, etc.), battery type, power rating, and type of network interface or connectivity (e.g., Bluetooth, WiFi, Zigbee, etc.). In certain embodiments, the identification module 304 may organize the heterogeneous devices 202 by their device class or some other classification.

Once the heterogeneous devices 202 are registered with the battery-status unification module 150, the query module 306 may be used to query the heterogeneous devices 202 with two-way communication capability for battery status information. The collection module 308 may receive this information from the heterogeneous devices 202. For example, the collection module 308 may receive one or more of battery capacity information 330, battery charge level information 332, voltage information 334, current information 336, and battery temperature information 338 from the heterogeneous devices 202 that have the ability to respond to the query. For heterogeneous devices 202 with one-way communication capability, the collection module 308 may collect the above-described information at specific times or intervals. In certain embodiments, the data collected by the collection module 308 may be stored and accumulated in a database over time, thereby providing a history of the battery status information for each of the heterogeneous devices 202.

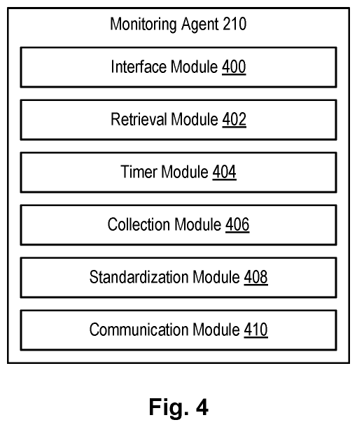

In certain embodiments, a standardization module 310 may be used to convert data received from the heterogeneous devices 202 to a standardized format. In certain embodiments, this conversion may occur at the centralized hub 212 and associated battery-status unification module 150. In other embodiments, this may occur at the monitoring agent 210 as will be discussed in association with FIG. 4.

The crowdsourced data collection module 312 may gather crowdsourced data 206 related to the heterogeneous devices 202, and more particularly with respect to the battery and energy usage associated with the heterogeneous devices 202. This data 206 may be helpful to predict the remaining battery life, and/or when to charge or replace a battery. In certain embodiments, the crowdsourced data 206 is gathered from a significant population of users of the devices 202 to shed light on the battery characteristics and energy usage associated with the heterogeneous devices 202. For example, crowdsourced data 206 may include information such as battery capacity 340, energy usage 342 of a device 202, and/or battery recharge time 344 among other types of information. In some cases, real-world crowdsourced data 206 may be used to augment manufacturer-released data and/or supplement historical data gathered from the heterogeneous devices 202 by way of the collection module 308. In some cases, the crowdsourced data 206 may be all that is available, particularly with “dumb” devices that may not have the ability to communicate their battery status or energy usage to the battery-status unification module 150.

Using the historical data and/or the crowdsourced data 206, the prediction module 314 may make various predictions with respect to the battery status and or energy usage of the heterogeneous devices 202. For example, the prediction module 314 may predict the remaining battery life of a device 202. In certain embodiments, the remaining battery life may be represented as a time remaining until discharge. Other predictions related to the battery and energy usage of a device 202 may be made by the prediction module 314 and are within the scope of the invention. The machine learning module 316 may provide artificial intelligence and more specifically machine learning prediction models or algorithms to assist the prediction module 314 in recognizing, using the historical data and/or the crowdsourced data 206, patterns or trends in battery characteristics and/or energy usage associated with particular heterogeneous devices 202 in order to more accurately make predictions.

The policy module 318 may be configured to establish or enable a user to establish policies for the heterogeneous devices 202. For example, the policy module 318 may enable one or more thresholds to be set for a particular device 202 that will trigger notifications or other actions when the thresholds are reached. These thresholds may be related to the remaining battery life associated with a device 202 and/or the replacement of a battery associated with a particular device 202. The alert module 320, by contrast, may be configured to send a notification (e.g., text message, push notification, email, etc.) when a threshold is reached. For example, if the remaining battery life for a device 202 falls below a selected threshold established by the policy module 318, the alert module 320 may send a notification to a user so that the battery can be recharged prior to depletion of the battery. In another embodiment, if the age of a battery has reached a selected threshold, the alert module 320 may notify a user so that the battery can be replaced prior to failure. In certain embodiments, the alert module 320 may also include an automated decision-making component that is capable of turning devices 202 that are being monitored by the battery-status unification module 150 off or placing them in a low power mode when availability is not critical in order to extend battery life.

The presentation module 322 may present the battery status information associated with the heterogeneous devices 202 in a unified manner. In certain embodiments, the presentation module 322 may provide a dashboard 208 as previously discussed that provides a single location or interface to present battery status information for many or all of a user's or entity's heterogeneous devices 202. The information associated with each heterogeneous device 202 may be presented as a row in a list or table, or on a map or graph that shows approximate locations or some other logical arrangement or grouping of the heterogeneous devices 202 in two or three dimensions. Alternatively or additionally, certain classes of heterogeneous devices 202 (security devices 202 for example) may be grouped or shown together on the dashboard 208 such that their battery status information is shown in close proximity to other devices 202 of the same or similar type.

FIG. 4 is a high-level block diagram showing a monitoring agent 210 and various internal sub-modules in accordance with the invention. As shown, in certain embodiments, the monitoring agent 210 may include one or more of an interface module 400, retrieval module 402, timer module 404, collection module 406, standardization module 408, and communication module 410.

The interface module 400 may enable the monitoring agent 210 to interface with various types of heterogeneous devices 202. For example, the interface module 400 may enable the monitoring agent 210 to communicate with the operating system and/or hardware that is specific to the heterogeneous device 202. This may include, for example, making appropriate system calls and/or requests through an application programming interface of the heterogeneous device 202 to retrieve battery status or other types of information.

In response to receiving a query from the battery-status unification module 150, the retrieval module 402 may be configured to retrieve battery status or other types of information from the heterogeneous device 202. Alternatively or additionally, particularly in heterogeneous devices 202 that only have one-way communication capability, the timer module 404 may periodically trigger the retrieval module 402 to retrieve battery status information from the heterogeneous device 202.

The collection module 406 may collect the battery status information that has been retrieved by the retrieval module 402 and the standardization module 408 may convert the battery status information to a standardized format, assuming the conversion occurs within the monitoring agent 210 and not the battery-status unification module 150. The communication module 410 may then communicate the battery status information to the battery-status unification module 150.

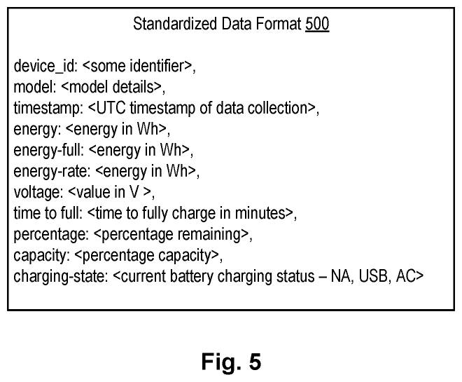

FIG. 5 shows one example of a standardized format 500 that may be used to represent battery status and characteristics for each heterogeneous device 202. This is simply an example and is not intended to be limiting. More or less information may be included in the standardized format 500. In the illustrated example, the standardized format 500 is represented in JSON (JavaScript Object Notation). As shown, in certain embodiments, the standardized format 500 includes one or more of a device identifier, device model, timestamp indicating when data was collected, battery energy level, battery energy capacity, energy rate, battery voltage, battery recharge time, remaining battery charge, percentage capacity remaining in a battery, and a charging state of a battery.

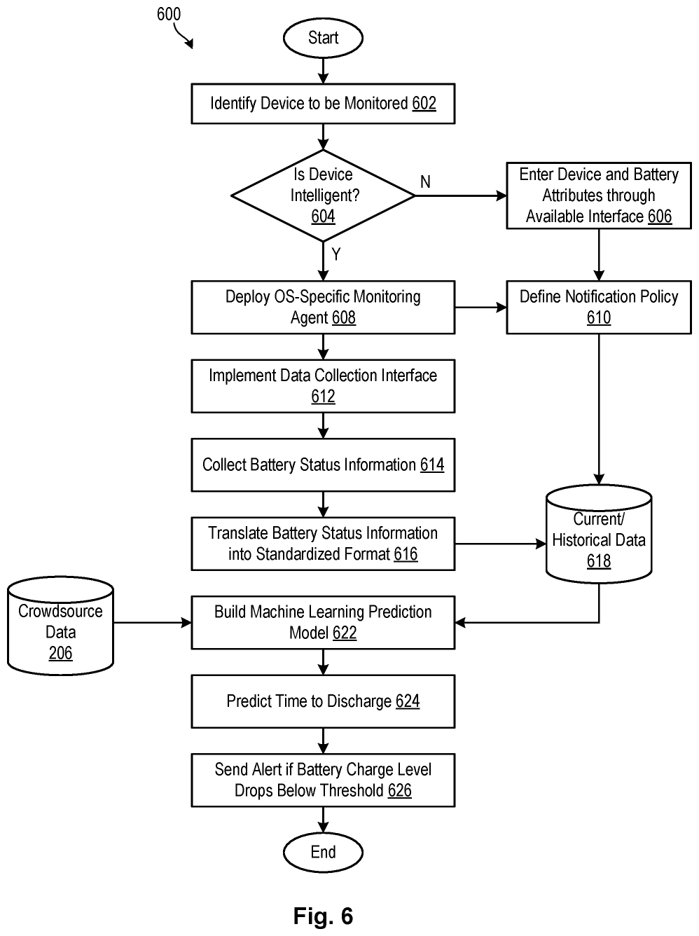

Referring to FIG. 6, one embodiment of a method 600 for unifying battery-status observability across a plurality of heterogeneous devices 202 is illustrated. In certain embodiments, such a method 600 may be executed by the battery-status unification module 150 and monitoring agents 210 previously discussed. This method 600 is presented by way of example and not limitation. As shown, the method 600 initially identifies 602 a device 202 to be monitored by the battery-status unification module 150. The method 600 then determines 604 whether the device is intelligent (i.e., whether the device 202 is a “smart” device or a “dumb” device). If the device 202 is not intelligent, the method 600 enables entering 606 device and battery attributes through an available interface. If the device 202 is intelligent, the method 600 deploys 608 an operating-system-specific monitoring agent 210 on the device 202. At this point, the method 600 may establish 610 or enable a user to establish 610 a notification policy for the device 202. This may include defining 610 one or more thresholds (e.g., remaining battery life thresholds, battery age thresholds, etc.) that, when reached, will trigger sending a notification to a user.

In the event the device 202 is an intelligent device, the method 600 implements 612 a data collection interface on the device 202 and collects 614 battery status information from the device 202 with the deployed monitoring agent 210. The method 600 then translates 616 the collected battery status information into a standardized format. This translation may occur at the monitoring agent 210 or the battery-status unification module 150. The collected battery status information may be stored by the battery-status unification module 150 and is represented in FIG. 6 as current/historical data 618. At the same time, crowdsourced data 206, as previously described in association with FIG. 2, may also be collected.

The method 600 then builds 622 a machine-learning prediction model that utilizes the current/historical data 618 and/or the crowdsourced data 206 to make various predictions. For example, the method 600 may utilize the machine learning model to predict 624 an amount time until the battery of the device 202 will discharge based on current or predicted usage. In the event a battery charge level drops below a designated threshold, the method 600 notifies 626 a user.

The flowcharts and block diagrams in the Figures illustrate the architecture, functionality, and operation of possible implementations of systems, methods, and computer program products according to various embodiments of the present invention. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other implementations may not require all of the disclosed steps to achieve the desired functionality. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

1. A method for unifying battery-status observability across a plurality of heterogeneous devices, the method comprising:
identifying a plurality of heterogeneous devices, each device comprising a battery to power the device;
monitoring a battery status of each device of the heterogeneous devices over a period of time to generate historical battery status information;
using the historical battery status information, utilizing machine learning to predict remaining battery life for each device of the heterogeneous devices; and
presenting the remaining battery life of each of the heterogeneous devices on a unified dashboard.

2. The method of claim 1, further comprising installing a monitoring agent on each device of the heterogeneous devices.

3. The method of claim 2, wherein monitoring a battery status of each device comprises monitoring a battery status of each device with the device's monitoring agent.

4. The method of claim 1, further comprising alerting a user in the event the remaining battery life of a device of the heterogeneous devices falls below a selected threshold.

5. The method of claim 1, wherein the remaining battery life is represented as an estimated time until discharge of the battery.

6. The method of claim 1, further comprising converting the battery status of each device of the heterogeneous devices into a standard format prior to presentation on the unified dashboard.

7. The method of claim 1, further comprising accessing crowdsourced data to determine battery life associated with each device of the heterogeneous devices and using the crowdsourced data in addition to the historical battery status information to predict the remaining battery life for each of the heterogeneous devices.

8. A computer program product for unifying battery-status observability across a plurality of heterogeneous devices, the computer program product comprising a computer-readable storage medium having computer-usable program code embodied therein, the computer-usable program code configured to perform the following when executed by at least one processor:
identify a plurality of heterogeneous devices, each device comprising a battery to power the device;
monitor a battery status of each device of the heterogeneous devices over a period of time to generate historical battery status information;
using the historical battery status information, utilize machine learning to predict remaining battery life for each device of the heterogeneous devices; and
present the remaining battery life of each of the heterogeneous devices on a unified dashboard.

9. The computer program product of claim 8, wherein the computer-usable program code is further configured to install a monitoring agent on each device of the heterogeneous devices.

10. The computer program product of claim 9, wherein monitoring a battery status of each device comprises monitoring a battery status of each device with the device's monitoring agent.

11. The computer program product of claim 8, wherein the computer-usable program code is further configured to alert a user in the event the remaining battery life of a device of the heterogeneous devices falls below a selected threshold.

12. The computer program product of claim 8, wherein the remaining battery life is represented as an estimated time until discharge of the battery.

13. The computer program product of claim 8, wherein the computer-usable program code is further configured to convert the battery status of each device of the heterogeneous devices into a standard format prior to presentation on the unified dashboard.

14. The computer program product of claim 8, wherein the computer-usable program code is further configured to access crowdsourced data to determine battery life associated with each device of the heterogeneous devices and use the crowdsourced data in addition to the historical battery status information to predict the remaining battery life for each of the heterogeneous devices.

15. A system for unifying battery-status observability across a plurality of heterogeneous devices, the system comprising:
at least one processor;
at least one memory device operably coupled to the at least one processor and storing instructions for execution on the at least one processor, the instructions causing the at least one processor to:
identify a plurality of heterogeneous devices, each device comprising a battery to power the device;
monitor a battery status of each device of the heterogeneous devices over a period of time to generate historical battery status information;
using the historical battery status information, utilize machine learning to predict remaining battery life for each device of the heterogeneous devices; and
present the remaining battery life of each of the heterogeneous devices on a unified dashboard.

16. The system of claim 15, wherein the instructions further cause the at least one processor to install a monitoring agent on each device of the heterogeneous devices.

17. The system of claim 16, wherein monitoring a battery status of each device comprises monitoring a battery status of each device with the device's monitoring agent.

18. The system of claim 15, wherein the instructions further cause the at least one processor to alert a user in the event the remaining battery life of a device of the heterogeneous devices falls below a selected threshold.

19. The system of claim 15, wherein the remaining battery life is represented as an estimated time until discharge of the battery.

20. The system of claim 15, wherein the instructions further cause the at least one processor to convert the battery status of each device of the heterogeneous devices into a standard format prior to presentation on the unified dashboard.
